(19) United States
(12) Patent Application Publication
(10) Pub. No.: US 2026/0076270 A1
(43) Pub. Date: Mar. 12, 2026

(54) DEVICE INCLUDING CONDUCTIVE POSTS THERMALLY COUPLING A DIE AND AN INTERPOSER STRUCTURE

(71) Applicant: QUALCOMM Incorporated, San Diego, CA (US)

(72) Inventors: Aniket PATIL, San Diego, CA (US); Bohan YAN, San Diego, CA (US); Manuel ALDRETE, Encinitas, CA (US); Piyush GUPTA, San Diego, CA (US)

(21) Appl. No.: 18/830,982

(22) Filed: Sep. 11, 2024

(51) Int. Cl. H01L 23/498; H01L 21/48; H01L 21/56; H01L 23/00; H01L 23/31; H01L 23/367; H01L 25/10; H10B 80/00

(52) U.S. Cl. CPC H10W 90/701; H10B 80/00; H10W 40/22; H10W 70/093; H10W 70/685; H10W 74/016; H10W 74/117; H10W 90/00; H10W 70/60; H10W 72/07236; H10W 72/223; H10W 90/288; H10W 90/722; H10W 90/724; H10W 90/754

(57) ABSTRACT

A device includes a substrate and a die. A first side of the die is electrically coupled to the substrate. The device also includes interconnect conductors electrically coupled to the die through conductive paths of the substrate. The device also includes an interposer structure that includes a first side and a second side. The first side includes first contacts electrically coupled to the interconnect conductors, and the second side includes second contacts. The interposer structure also includes a plurality of patterned conductive structures electrically coupled to the first contacts and to second contacts. The device further includes a plurality of conductive posts between a second side of the die and to the first side of the interposer structure and configured to conduct heat from the die to the interposer structure.

### FIELD

Various features relate to integrated devices that include one or more dies and one or more interposer structures.

### DESCRIPTION OF RELATED ART

Electrical connections exist at each level of a system hierarchy. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. More recently, the number of interconnect levels for circuitry has substantially increased due to the large number of devices that are now interconnected in a modern electronic device. The increased number of interconnect levels for supporting the increased number of devices involves more intricate processes.

In state-of-the-art electronic devices, there is generally an expectation that integrated device packages have a small form factor, a low cost, a tight power budget, and high performance. These various goals are often in conflict. As an example, assembling components of an electronic device into a package with a smaller form factor generally impedes heat management, which limits performance of the electronic device.

### SUMMARY

Various features relate to integrated circuit devices.

One example provides a device that includes a substrate and a die. A first side of the die is electrically coupled to the substrate. The device also includes interconnect conductors electrically coupled to the die through conductive paths of the substrate. The device also includes an interposer structure that includes a first side and a second side. The first side includes first contacts electrically coupled to the interconnect conductors, and the second side includes second contacts. The interposer structure also includes a plurality of patterned conductive structures electrically coupled to the first contacts and to the second contacts. The device further includes a plurality of conductive posts between a second side of the die and the first side of the interposer structure and configured to conduct heat from the die to the interposer structure.

Another example provides a method of fabrication that includes coupling a first side of a first die to a first substrate and coupling interconnect conductors between the first substrate and an interposer structure. The method also includes coupling conductive posts to a second side of the first die to provide thermal conduction paths between the first die and the interposer structure.

Another example provides an integrated device that includes a first substrate and a first die. A first side of the first die is electrically coupled to the first substrate. The integrated device also includes a second die and an interposer structure disposed between the first die and the second die. The interposer structure defines conductive paths that electrically couple the first die and second die. The integrated device also includes a plurality of conductive posts between a second side of the first die and a first side of the interposer structure and configured to conduct heat from the first die to the interposer structure.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a schematic cross-sectional profile view of an exemplary device that includes conductive posts thermally coupling a die and an interposer structure.

FIG. 2 illustrates a schematic cross-sectional profile view of another exemplary device that includes conductive posts thermally coupling a die and an interposer structure.

FIG. 3A illustrates a first part of an exemplary sequence for fabricating an exemplary device that includes conductive posts thermally coupling a die and an interposer structure.

FIG. 3B illustrates a second part of the exemplary sequence for fabricating an exemplary device that includes conductive posts thermally coupling a die and an interposer structure.

FIG. 4 illustrates an alternative second part of the exemplary sequence of FIGS. 3A-3B.

FIG. 5 illustrates an exemplary flow diagram of a method of fabrication for a device that includes conductive posts thermally coupling a die and an interposer structure.

FIG. 6 illustrates various electronic devices that may integrate conductive posts thermally coupling a die and an interposer structure described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, components and circuitry may be shown in block diagrams in order to avoid obscuring the aspects in unnecessary detail. In other instances, well-known structures and techniques may not be shown in detail in order not to obscure the aspects of the disclosure. As another example, various devices and structures disclosed herein are illustrated schematically. Such schematic representations are not to scale and are generally intentionally simplified. To illustrate, integrated devices can have many tens or hundreds of contacts and corresponding interconnections; however, a very small number of such contacts and interconnects are illustrated herein to highlight important features of the disclosure without unduly complicating the drawings.

Particular aspects of the present disclosure are described below with reference to the drawings. In the description, common features are designated by common reference numbers. As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular or optional plural (as indicated by “(s)”) unless aspects related to multiple of the features are being described.

In some drawings, multiple instances of a particular type of feature are shown. In some circumstances, fewer than all of such features may be identified using a reference number. For example, a single reference number may be shown and associated with a representative instance of the feature so as not to obscure other aspects of the drawings.

As used herein, the terms “comprise,” “comprises,” and “comprising” may be used interchangeably with “include,” “includes,” or “including. ” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

As used herein, the term “layer” includes a film, and is not construed as indicating a vertical or horizontal thickness unless otherwise stated. As used herein, the term “chiplet” may refer to an integrated circuit block, a functional circuit block, or other like circuit block specifically designed to work with one or more other chiplets to form a larger, more complex chiplet architecture.

Improvements in manufacturing technology and demand for lower cost and more capable electronic devices has led to increasing complexity of integrated circuits (ICs). Often, more complex ICs have more complex interconnection schemes to enable interaction between ICs of a device. The number of interconnect levels for circuitry has substantially increased due to the large number of devices that are now interconnected in a state-of-the-art device.

These interconnections include back-end-of-line (BEOL) interconnect layers, which may refer to the conductive interconnect layers for electrically coupling to front end-of-line (FEOL) active devices of an IC. The various BEOL interconnect layers are formed at corresponding BEOL interconnect levels, in which lower BEOL interconnect levels generally use thinner metal layers relative to upper BEOL interconnect levels. The BEOL interconnect layers may electrically couple to middleof-line (MOL) interconnect layers, which interconnect to the FEOL active devices of an IC.

State-of-the-art electronic devices (e.g., portable computing devices, mobile communication devices, wearable devices, special purpose computing devices, etc.) demand a small form factor, low cost, a tight power budget, and high electrical performance. Integrated circuit package design has evolved to meet these divergent goals. One approach to reducing package size is to integrate multiple dies within a single package. One example of a multi-die package is a two-dimensional (2D) package architecture, in which two or more dies are coupled to a package substrate side-by-side with one another. Dies in this configuration can interact with one another (e.g., via die-to-die connections) and with off-package devices (e.g., via off-package connections). A challenge of such configurations is that die-to-die and off-package connections have different design criteria. For example, off-package connections are generally larger (e.g., in terms of line width, line spacing, etc.) than is needed for die-to-die connections. Various workarounds have been used to address this size difference. For example, additional devices (e.g., interposer devices or bridge die) can be added to a package to route die-to-die connections using smaller lines. As another example, additional layers or a separate stacked substrate can be added to the package substrate to provide die-to-die connection and redistribution routing to couple to off-package connections.

Another approach to reducing package size is a 2.5D architecture, in which two or more devices are positioned side-by-side with one another on the package substrate, and one or more additional devices are stacked on at least one of the side-by-side devices. To illustrate, a stacked die arrangement can be coupled to a package substrate side-by-side with another die, a passive device, another die stack, etc. Stacked die schemes and chiplet architectures are becoming more common as significant power performance area (PPA) yield enhancements are demonstrated for stacked die and chiplet architecture product lines.

While stacking dies or packaged IC devices has several benefits, heat management can be problematic when such stacking schemes are used. Disclosed devices are configured for use in a stacked configuration, such as a package-on-package (POP) configuration and include features to facilitate heat removal. Thus, the disclosed devices are able to take advantage of the various benefits of POP configurations, such as small form factor, without the associated heat management issues. In particular, the disclosed devices include conductive posts thermally coupling a die and an interposer structure. The conductive posts provide a thermal conduction path to manage heating of the die without negatively impacting other aspects of the devices, such as the number or arrangement of input/output conductors between the die and the interposer structure. The disclosed devices can be assembled using conventional processes that are relatively low cost and have relatively high reliability.

### Exemplary Device Including Conductive Posts Thermally Coupling a Die and an Interposer Structure

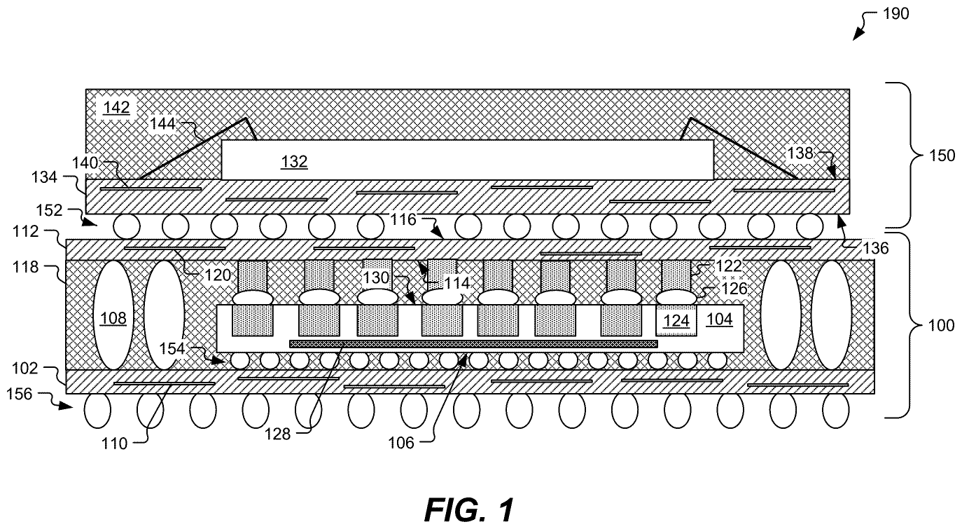

FIG. 1 illustrates a schematic cross-sectional profile view of an exemplary device 100 that includes conductive posts 122 thermally coupling a die 104 and an interposer structure 112. In the example illustrated in FIG. 1, the device 100 includes or corresponds to a first packaged integrated circuit (IC) device, and a second packaged IC device 150 (also referred to herein as device 150) is stacked on (and electrically coupled to) the interposer structure 112 to form a package-on-package (POP) device 190.

As used herein, a “packaged integrated circuit device” refers to an assembly that includes one or more dies, a substrate electrically coupled to the die(s) and including electrical connections (e.g., pads, contacts, or interconnects) to enable interconnection of the die(s) to other components. Optionally, a packaged IC device can include other components as well, such as passive electronic components. A packaged IC device often also includes features to protect the die(s), interconnects, and/or other components. For example, in FIG. 1, the device 100 includes mold compound 118 that at least partially encapsulates the die 104 (and optionally other features or components of the device 100) to provide protection from moisture, dust, or other contaminants, to provide mechanical protection, etc. Likewise, in FIG. 1, the device 150 includes mold compound 142 that at least partially encapsulates a die 132 (and optionally other features or components of the device 150) to provide similar protection.

Further, as used herein, a “POP device” refers to an assembly that includes two or more packaged IC devices stacked one upon another and electrically interconnected. For example, in FIG. 1, the device 100 is electrically coupled to the device 150 by conductive interconnects 152 to enable the die 104 and the die 132 to exchange signals. In particular, in FIG. 1, the die 104 is electrically coupled to conductive structures 110 of a substrate 102 by conductive interconnects 154, the conductive structures 110 of the substrate 102 are electrically coupled to interconnect conductors 108, and the interconnect conductors 108 are electrically coupled to conductive structures 120 of the interposer structure 112. Similarly, the die 132 is electrically coupled to conductive structures 140 of a substrate 134 by conductive interconnects 144, and the conductive structures 140 of the substrate 134 are electrically coupled to the conductive structures 120 of the interposer structure 112 by the conductive interconnects 152. The various conductive interconnects described herein can include, for example, microbumps, solder balls, copper-clad solder balls, conductive pillars, conductive pads (e.g., for pad-to-pad bonding), etc.

Configuring packaged IC devices in a POP configuration has many advantages, such as enabling dies that interact with one another frequently, such as a processor die and a memory die, to be placed in close proximity to one another, which provides shorter signal paths. Shorter signal paths tend to be associated with faster communication speeds, improved signal integrity, and lower power consumption than longer signal paths. Another advantage is that POP devices can include the same components as devices with a side-by-side configuration in a smaller footprint. However, one challenge associated with POP configurations is removal of heat from dies within the POP device. For example, die(s) in the bottom packaged IC device of a POP device may be largely or completely encapsulated with mold compound, which is not a good thermal conductor. Further, the bottom packaged IC device of a POP device generally includes or is coupled to an interposer structure, making access to the die(s) of the bottom packaged IC device difficult.

The device 100 addresses these and other concerns by including the conductive posts 122. The conductive posts 122 are in thermal contact with the die 104 and in thermal contact with the interposer structure 112, providing a thermal conduction path to manage heating of the die 104. In some examples, the die 104 can also include features that further improve heat management. For example, in a flip chip arrangement, a face (e.g., a first side 106) of the die 104 is adjacent to the substrate 102 of the device 100 (e.g., the bottom packaged IC device). Active components within an active region 128 of the die 104 are responsible for most or all of the heat generated by the die 104. In this example, the die 104 can include embedded thermally conductive structures 124 (e.g., metal filled vias), that extend from the back of the die 104 (e.g., a second side 130) toward the active region 128. In this example, the embedded thermally conductive structures 124 are thermally coupled to the conductive posts 122 (e.g., via solder 126 or direct contact). In this configuration, the embedded thermally conductive structures 124 increase thermal communication between the active components in the active region 128 and the conductive posts 122. It should be noted, however, that the embedded thermally conductive structures 124 are optional and may be omitted in situations in which sufficient heat can be removed from the die 104 without the embedded thermally conductive structures 124 and/or in situations in which formation of the embedded thermally conductive structures 124 would be too expensive or complex.

The substrates 102, 134 and the interposer structure 112 include one or more dielectric layers intermingled with two or more metal layers. The metal layers are patterned to define conductive pathways that form the conductive structures 110, 120, 140. The conductive structures 110, 120, 140 can include metal lines, vias, contacts, pads, and other similar features, and the conductive pathways formed by the conductive structures 110, 120, 140 can extend between locations (e.g., contacts) on the same side of the respective substrate or interposer structure, between locations (e.g., contacts) on opposite sides of the respective substrate or interposer structure, or combinations thereof. For example, the conductive structures 140 can include first contacts on a first side 138 of the substrate 134, second contacts on a second side 136 of the substrate 134 and can define conductive pathways between one or more of the first contacts and one or more of the second contacts. As another example, the conductive structures 120 can include first contacts on a first side 114 of the interposer structure 112, second contacts on a second side 116 of the interposer structure 112 and can define conductive pathways between one or more of the first contacts and one or more of the second contacts. In the above examples, at least some of the second contacts of the interposer structure 112 are electrically coupled to at least some of the second contacts of the substrate 134 by the conductive interconnects 152. Further, at least some of the first contacts of the interposer structure 112 are electrically coupled to first contacts on a first side of the substrate 102 formed by the conductive structures 110 of the substrate 102. The conductive structures 110 of the substrate 102 can also include second contacts on a second side of the substrate 102, which can be electrically coupled to conductive interconnects 156 to form off package connections (e.g., connections to a printed circuit board).

In some embodiments, the substrate 102, the interposer structure 112, or both, can be pre-formed and subsequently attached to other components to form the device 100. For example, the substrate 102, the interposer structure 112, or both, can be formed by laying up or laminating metal layers and one or more pre-preg layers on a carrier. In this example, the metal layers can be patterned as needed to form the conductive structures during the layup or lamination process to define conductive pathways and contacts. Subsequently, the structure so formed can be removed from the carrier, and optionally cut, to form one or more substrates 102 or one or more interposer structures 112. In other embodiments, the substrate 102, the interposer structure 112, or both, can be formed in place on other components of the device 100. For example, the interposer structure 112 can be formed of dielectric layers and patterned metal layers applied on the mold compound 118. As used herein, layers formed in place on other components of the device 100 or the device 150 are referred to as “redistribution layers” to distinguish from layers built separately (e.g., on a carrier) and attached to other components to form a device, which are referred to as “pre-formed layers”. Like the substrate 102 of the device 100, the substrate 134 of the device 150 can include a set of redistribution layers or a set of pre-formed layers.

Each die of the POP device 190 (e.g., the die 104, the die 132, and optionally one or more additional dies of the device 100 or the device 150) can include integrated circuitry, such as a plurality of transistors and/or other circuit elements arranged and interconnected to form logic cells, memory cells, etc. Components of the integrated circuitry can be formed in and/or over a semiconductor substrate. For example, in FIG. 1, the die 104 includes an active region 128 proximate to a first side 106 of the die 104. In this example, the first side 106 of the die 104 is commonly referred to as a face of the die 104, as distinct from a back of the die 104 which refers to a second side 130 opposite the first side 106. The active region 128 includes conductors, doped semiconductor regions, undoped semiconductor regions, and possibly other materials which together define integrated circuitry including, for example, transistors, passive components, conductive paths, etc. Different implementations can use different types of transistors, such as a field effect transistor (FET), planar FET, finFET, a gate all around FET, or mixtures of transistor types. In some implementations, a front end-of-line (FEOL) process may be used to fabricate the integrated circuitry in and/or over the semiconductor substrate.

In some implementations, a packaged IC device (e.g., the device 100 or the device 150) of the POP device 190 can include two or more dies arranged in a stacked three-dimensional (3D) arrangement. In some implementations, one or both of the dies 104, 132 include one or more microcontrollers, application specific integrated circuits (ASICs), field programmable gate arrays (FPGAs), central processing units (CPUs) having one or more processing cores, processing systems, system on chip (SoC), or other circuitry and logic configured to facilitate the operations of the dies 104, 132 Additionally, or alternatively, one or both of the dies 104, 132 may include or operate as a memory, such as a static random-access memory (SRAM), a dynamic random-access memory (DRAM), flash memory, read-only memory (ROM), programmable read-only memory (PROM), erasable programmable read-only memory (EPROM), electrically erasable programmable read-only memory (EEPROM), a solid-state storage device (SSD), or a combination thereof. As one example, the die 104 can include circuitry defining one or more processor cores, and the die 132 can include circuitry defining a plurality of memory cells.

Thus, FIG. 1 illustrates an example of an integrated device (e.g., the POP device 190) that includes a first substrate (e.g., the substrate 102) and a first die (e.g., the die 104). The first die (e.g., the die 104) includes a first side (e.g., the first side 106) and a second side (e.g., the second side 130). The first side (e.g., the first side 106) of the first die (e.g., the die 104) is electrically coupled to the first substrate (e.g., the substrate 102).

The integrated device (e.g., the POP device 190) in this example also includes a second die (e.g., the die 132), and an interposer structure (e.g., the interposer structure 112) disposed between the first die (e.g., the die 104) and the second die (e.g., the die 132). The interposer structure (e.g., the interposer structure 112) includes conductive structures (e.g., the conductive structures 120) that define conductive paths forming portions of electrical paths between the first die (e.g., the die 104) and second die (e.g., the die 132).

The integrated device (e.g., the POP device 190) in this example further includes a plurality of conductive posts (e.g., the conductive posts 122) in thermal contact with the second side (e.g., the second side 130) of the first die (e.g., the die 104) and a first side (e.g., the first side 114) of the interposer structure (e.g., the interposer structure 112). In this example, the conductive posts (e.g., the conductive posts 122) facilitate heat removal from the first die (e.g., the die 104). To illustrate, in this example, the integrated device (e.g., the POP device 190) can also include mold compound (e.g., the mold compound 118) between the first substrate (e.g., the substrate 102) and the interposer structure (e.g., the interposer structure 112) and at least partially encapsulating the first die (e.g., the die 104) making removal of heat from the first die (e.g., the die 104) challenging. In this example, the conductive posts (e.g., the conductive posts 122) can extend through the mold compound (e.g., the mold compound 118) to improve thermal conduction from the first die (e.g., the die 104).

In some embodiments of this example, the first die (e.g., the die 104) includes embedded thermally conductive structures (e.g., the embedded thermally conductive structures 124), and one or more of the conductive posts (e.g., the conductive posts 122) is coupled, directly or by solder (e.g., the solder 126) to one of the embedded thermally conductive structures (e.g., the embedded thermally conductive structures 124). In such embodiments, the embedded thermally conductive structures (e.g., the embedded thermally conductive structures 124) further improve thermal conduction from an active region (e.g., the active region 128) of the first die (e.g., the die 104).

In some implementations, two or more packaged IC devices (e.g., the device 100 and the device 150) can be assembled to form a POP device (e.g., the POP device 190 of FIG. 1). In some such implementations, the POP device (e.g., the POP device 190) can be formed by a different entity or during different operations than one or more of the packaged IC devices (e.g., the device 100 and the device 150). Thus, it should be noted that FIG. 1 also illustrates an example of a device (e.g., the device 100) that includes a substrate (e.g., the substrate 102) and a die (e.g., the die 104) that includes a side (e.g., the first side 106) electrically coupled to the substrate (e.g., the substrate 102). In this example, the device (e.g., the device 100) also includes interconnect conductors (e.g., the interconnect conductors 108) electrically coupled to the die (e.g., the die 104) through conductive paths (e.g., conductive paths defined by the conductive structures 110) of the substrate (e.g., the substrate 102).

In this example, the device (e.g., the device 100) further includes an interposer structure (e.g., the interposer structure 112) that includes a first side (e.g., the first side 114), a second side (e.g., the second side 116), and a plurality of patterned conductive structures (e.g., the conductive structures 120). The first side (e.g., the first side 114) includes first contacts (e.g., contacts defined by the conductive structures 120 on the first side 114) electrically coupled to the interconnect conductors (e.g., the interconnect conductors 108), and the second side (e.g., the second side 116) includes second contacts (e.g., contacts defined by the conductive structures 120 on the second side 116).

In this example, the device (e.g., the device 100) also includes a plurality of conductive posts (e.g., the conductive posts 122) in thermal contact with a second side (e.g., the second side 130) of the die (e.g., the die 104) and the first side (e.g., the first side 114) of the interposer structure (e.g., the interposer structure 112). In this example, the conductive posts (e.g., the conductive posts 122) facilitate heat removal from the die (e.g., the die 104). To illustrate, in this example, the device (e.g., the device 100) can also include mold compound (e.g., the mold compound 118) between the substrate (e.g., the substrate 102) and the interposer structure (e.g., the interposer structure 112) and at least partially encapsulating the die (e.g., the die 104) making removal of heat from the die (e.g., the die 104) challenging. In this example, the conductive posts (e.g., the conductive posts 122) can extend through the mold compound (e.g., the mold compound 118) to improve thermal conduction from the die (e.g., the die 104).

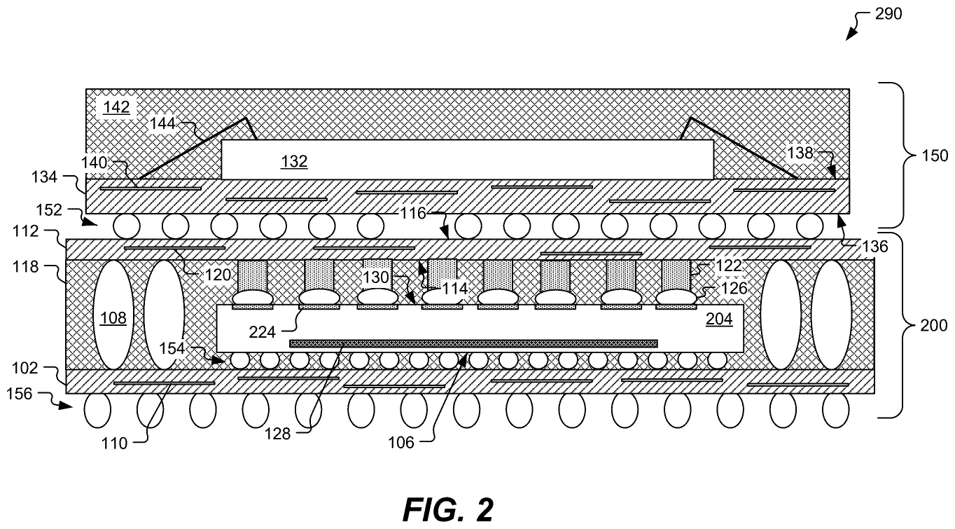

FIG. 2 illustrates a schematic cross-sectional profile view of another exemplary device 200 that includes the conductive posts 122 thermally coupling a die 204 and the interposer structure 112. The device 200 of FIG. 2 includes many of the same components and features as are described above with reference to FIG. 1. Such components and features are physically and operationally the same as described above with reference to FIG. 1 and are labeled in FIG. 2 using the same reference numbers.

In some implementations, the device 200 includes all of the same features and components as the device 100 of FIG. 1 except that the die 204 does not include embedded thermally conductive structures, such as the embedded thermally conductive structures 124 of the die 104 of FIG. 1. Rather, the die 204 includes contacts 224 on the second side 130 of the die 204, and the contacts 224 are coupled, directly or by the solder 126, to the conductive posts 122. In some embodiments, the die 204 can be thinned before the contacts 224 are formed to enable placement of the contacts 224 closer to the active region 128. However, whether the die 204 is thinned or not, heat transfer from the die 204 via the conductive structures 124 is greater than heat transfer from a die embedded in mold compound of a POP structure without the conductive structures 124.

Thus, FIG. 2 illustrates an example of an integrated device (e.g., the POP device 290) that includes a first substrate (e.g., the substrate 102) and a first die (e.g., the die 204). The first die (e.g., the die 204) includes a first side (e.g., the first side 106) and a second side (e.g., the second side 130). The first side (e.g., the first side 106) of the first die (e.g., the die 204) is electrically coupled to the first substrate (e.g., the substrate 102).

The integrated device (e.g., the POP device 290) in this example also includes a second die (e.g., the die 132), and an interposer structure (e.g., the interposer structure 112) disposed between the first die (e.g., the die 204) and the second die (e.g., the die 132). The interposer structure (e.g., the interposer structure 112) includes conductive structures (e.g., the conductive structures 120) that define conductive paths forming portions of electrical paths between the first die (e.g., the die 204) and second die (e.g., the die 132).

The integrated device (e.g., the POP device 290) in this example further includes a plurality of conductive posts (e.g., the conductive posts 122) in thermal contact with the second side (e.g., the second side 130) of the first die (e.g., the die 204) and a first side (e.g., the first side 114) of the interposer structure (e.g., the interposer structure 112). In this example, the conductive posts (e.g., the conductive posts 122) facilitate heat removal from the first die (e.g., the die 204). To illustrate, in this example, the integrated device (e.g., the POP device 290) can also include mold compound (e.g., the mold compound 118) between the first substrate (e.g., the substrate 102) and the interposer structure (e.g., the interposer structure 112) and at least partially encapsulating the first die (e.g., the die 204), making removal of heat from the first die (e.g., the die 204) challenging. In this example, the conductive posts (e.g., the conductive posts 122) can extend through the mold compound (e.g., the mold compound 118) to improve thermal conduction from the first die (e.g., the die 204). In the example of FIG. 2, the first die (e.g., the die 204) does not include embedded thermally conductive structures (e.g., the embedded thermally conductive structures 124 of FIG. 1), and the conductive posts (e.g., the conductive posts 122) are coupled, directly or by solder (e.g., the solder 126) to contacts (e.g., the contacts 224) of the first die (e.g., the die 204).

FIG. 2 also illustrates an example of a device (e.g., the device 200) that includes a substrate (e.g., the substrate 102) and a die (e.g., the die 204) that includes a side (e.g., the first side 106) electrically coupled to the substrate (e.g., the substrate 102). In this example, the device (e.g., the device 100) also includes interconnect conductors (e.g., the interconnect conductors 108) electrically coupled to the die (e.g., the die 204) through conductive paths (e.g., conductive paths defined by the conductive structures 110) of the substrate (e.g., the substrate 102).

In this example, the device (e.g., the device 200) further includes an interposer structure (e.g., the interposer structure 112) that includes a first side (e.g., the first side 114), a second side (e.g., the second side 116), and a plurality of patterned conductive structures (e.g., the conductive structures 120). The first side (e.g., the first side 114) includes first contacts (e.g., contacts defined by the conductive structures 120 on the first side 114) electrically coupled to the interconnect conductors (e.g., the interconnect conductors 108), and the second side (e.g., the second side 116) includes second contacts (e.g., contacts defined by the conductive structures 120 on the second side 116).

In this example, the device (e.g., the device 200) also includes a plurality of conductive posts (e.g., the conductive posts 122) in thermal contact with a second side (e.g., the second side 130) of the die (e.g., the die 204) and the first side (e.g., the first side 114) of the interposer structure (e.g., the interposer structure 112). In this example, the conductive posts (e.g., the conductive posts 122) facilitate heat removal from the die (e.g., the die 204). To illustrate, in this example, the device (e.g., the device 200) can also include mold compound (e.g., the mold compound 118) between the substrate (e.g., the substrate 102) and the interposer structure (e.g., the interposer structure 112) and at least partially encapsulating the die (e.g., the die 204), making removal of heat from the die (e.g., the die 204) challenging. In this example, the conductive posts (e.g., the conductive posts 122) can extend through the mold compound (e.g., the mold compound 118) to couple to the contacts 224 to improve thermal conduction from the die (e.g., the die 204).

It should be understood that the device 100 of FIG. 1, the device 200 of FIG. 2, or both, may include additional components, other components, fewer components, or a combination thereof, to support the functionality described herein. As non-limiting examples, the device 100 or the device 200 may include additional dies, additional packaged IC devices, additional interconnects, additional structures, other components, different components, or a combination thereof, to support the functionality and technical advantages disclosed herein.

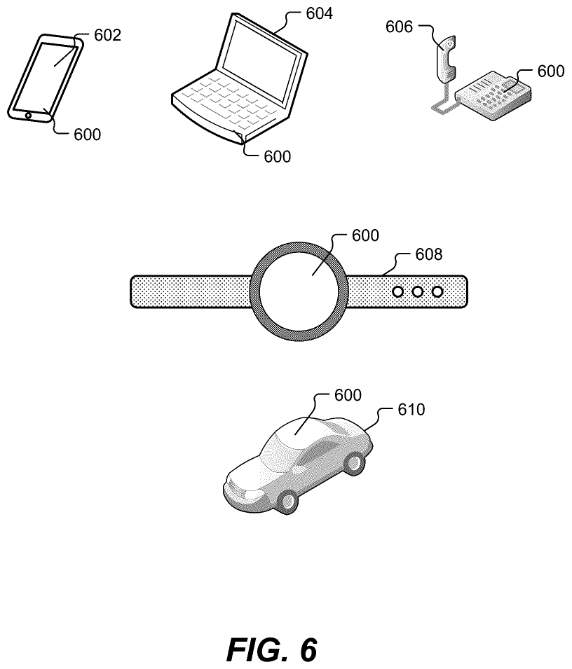

In various examples, the POP device 190, the POP device 290, or both, can be integrated in a smartphone, a tablet computer, a fixed location terminal device, an automobile, a wearable electronic device, a laptop computer, or some combination thereof, as described in more detail below with reference to FIG. 6. Further, the POP device 190, the POP device 290, or both, can be integrated with or included within a wide variety of other devices. For example, a device that includes the POP device 190, the POP device 290, or both, can include components such as a power management integrated circuit (PMIC), an application processor, a modem, a radio frequency (RF) device, a passive device, a filter, a capacitor, an inductor, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. In such devices, the POP device 190 or the POP device 290 can operate as any of these components (or a combination of these components) that includes active circuitry.

### Exemplary Sequence for Fabricating a Device Including Conductive Posts Thermally Coupling a Die and an Interposer Structure

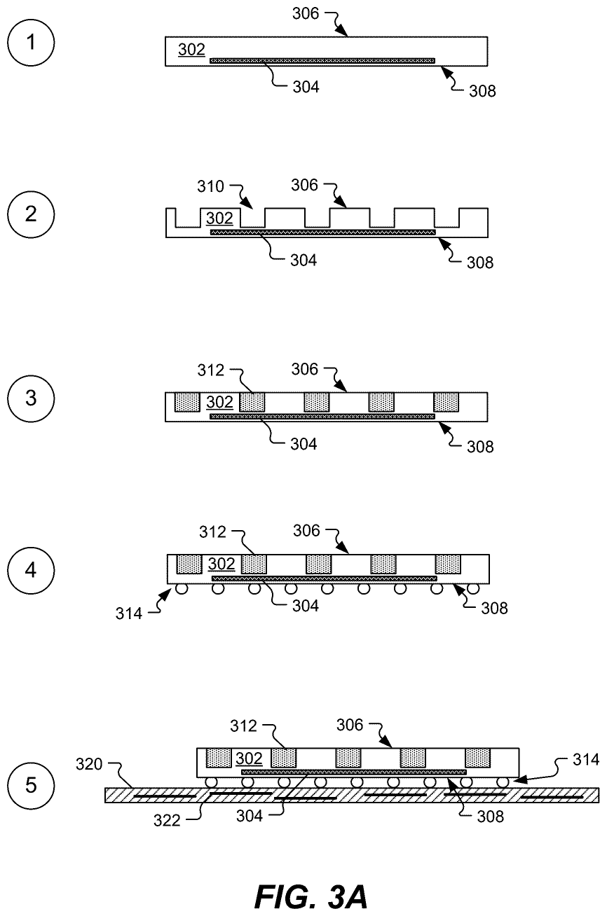

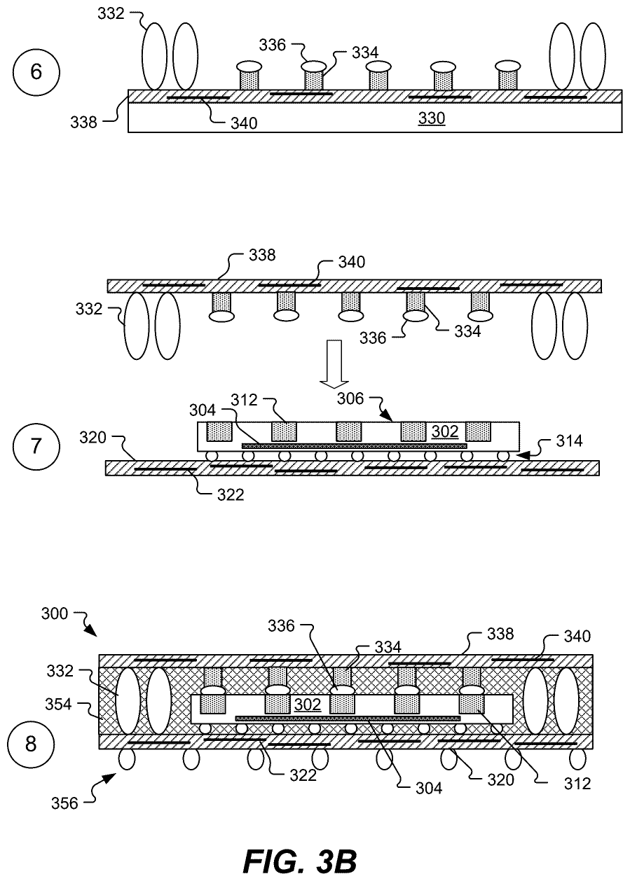

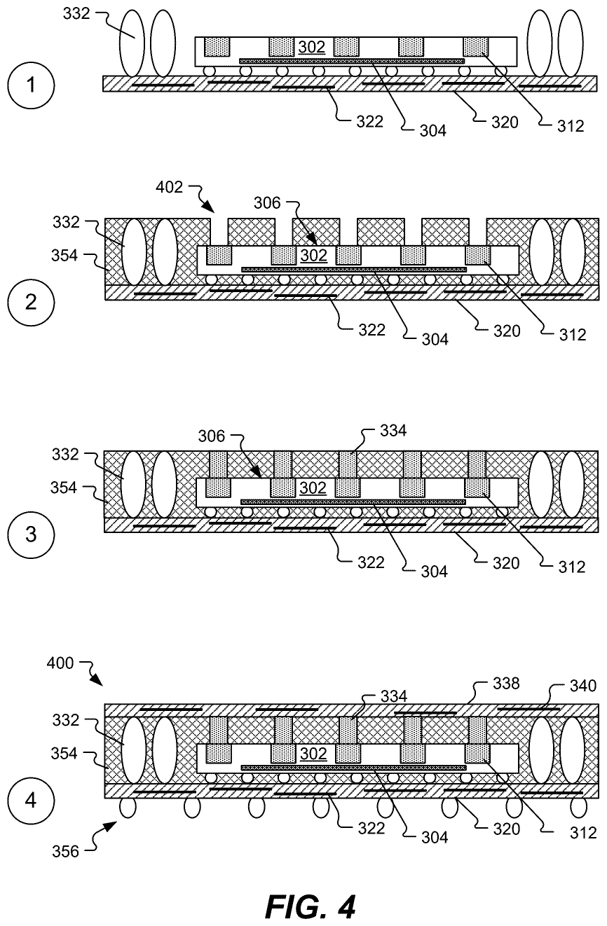

In some implementations, fabricating a device that includes conductive posts thermally coupling a die and an interposer structure (e.g., the device 100, the device 200, the POP device 190, or the POP device 290) includes several processes. FIGS. 3A and 3B illustrate an exemplary sequence for fabricating or providing a device that includes conductive posts thermally coupling a die and an interposer structure, as described with reference to any of FIGS. 1 and 2. In some implementations, the sequence of FIGS. 3A and 3B may be used to provide (e.g., during fabrication of) one or more of the device 100 of FIG. 1, the POP device 190 of FIG. 1, the device 200 of FIG. 2, or the POP device 290 of FIG. 2. FIG. 4 illustrates an alternative sequence that may be used in place of a portion of the sequence of FIGS. 3A and 3B. Specifically, the sequence of FIG. 4 can be used in place of the sequence of FIG. 3B.

It should be noted that the sequence of FIGS. 3A, 3B and 4 may combine one or more stages in order to simplify and/or clarify the sequence for providing or fabricating a device that includes conductive posts thermally coupling a die and an interposer structure. In some implementations, the order of the processes may be changed or modified. In some implementations, one or more of the processes may be replaced or substituted without departing from the scope of the disclosure. In the following description, reference is made to various illustrative Stages of the sequence, which are numbered (using circled numbers) in FIGS. 3A, 3B, and 4. Each of the various stages of the sequence illustrated in FIGS. 3A, 3B, and 4 shows a single device being formed; however, in some examples, a plurality of devices can be formed concurrently.

Stage 1 of FIG. 3A illustrates a state after formation of a die 302 that includes an active region 304 proximate a first side 308 (e.g., a face) of the die 302. For example, the die 302 can correspond to or include an example of the die 104 of FIG. 1 or FIG. 2. The die 302 can be formed using a variety of wafer-level FEOL operations to pattern conductors and components in or on a semiconductor substrate. Such wafer-level FEOL operations generally form the active region 304 on or near the face (e.g., the first side 308) of a wafer, leaving a backside of the wafer (corresponding to a second side 306 of the die 302) unpatterned. In some cases, after formation of features and components within the active region 304, the backside of the wafer can be ground to thin the wafer (and dies formed therefrom) for various purposes, such as to reduce package dimensions, to improve heat transfer, etc. At Stage 1, the second side 306 can correspond to the backside of the wafer before or after thinning.

Stage 2 of FIG. 3A illustrates a state after formation of openings 310. The openings 310 extend from the second side 306 toward the active region 304. The openings 310 can be formed using various material removal operations, such as etching guided by a patterned resist layer. Although the openings 310 can be formed using device-level (e.g., die-level) operations, it would generally be more efficient to use strip-level, panel-level, or wafer-level operations.

Formation of the openings 310 is optional and is omitted in some implementations. For example, during formation of the die 204 of FIG. 2, such openings 310 are not formed, and operations associated with Stage 2 can be omitted from the sequence of operations used during fabrication.

Stage 3 of FIG. 3A illustrates a state after formation of thermally conductive structures 312 within the openings 310. For example, the thermally conductive structures 312 can correspond to or include examples of the embedded thermally conductive structures 124 of FIG. 1. The thermally conductive structures 312 can be formed using various additive operations to deposit thermally conductive materials (e.g., one or more metals) within the openings. Examples of such additive operations include, without limitation, chemical vapor deposition (CVD), physical vapor deposition (PVD), sputtering, printing, or plating. Although the thermally conductive structures 312 can be formed using device-level (e.g., die-level) operations, it would generally be more efficient to use strip-level, panel-level, or wafer-level operations.

Formation of the thermally conductive structures 312 is optional and is omitted in some implementations. For example, during formation of the die 204 of FIG. 2, such thermally conductive structures 312 are not formed. In examples in which the openings 310 and the thermally conductive structures 312 are not formed, additive operations similar to those used to form the thermally conductive structures 312 can be used to form contacts (e.g., the contacts 224) on the second side 306 of the die 302. For example, a metal layer or a seed layer can be formed on the second side 306 of the die 302 to form or to facilitate formation of the contacts 224 of FIG. 2. In this example, the metal layer or the seed layer can be formed using CVD, PVD, sputtering, printing, or plating operations.

Stage 4 of FIG. 3A illustrates a state after conductive interconnects 314 are formed on or coupled to the first side 308 of the die 302. For example, the conductive interconnects 314 can correspond to or include examples of the conductive interconnects 154 of FIG. 1 or FIG. 2. The conductive interconnects 314 can include, for example, solder balls, solder bumps, conductive posts, or pads (e.g., for pad-to-pad bonding). The conductive interconnects 314 can be formed on or coupled to the die 302 using device-level (e.g., die-level) operations, strip-level operations, panel-level operations, or wafer-level operations.

Stage 5 of FIG. 3A illustrates a state after the die 302 is coupled, via the conductive interconnects 314, to a substrate 320. The substrate 320 can include one or more dielectric layers intermingled with two or more metal layers to define conductive structures 322. The conductive structures 322 can include metal lines, vias, contacts, pads, and other similar features. For example, the substrate 320 can include or correspond to an example of the substrate 102 of FIG. 1 or FIG. 2, and the conductive structures 322 can include or correspond to an example of the conductive structures 110 of FIG. 1 or FIG. 2. The die 302 can be coupled to the substrate 320 using die attach operations, such as solder reflow operations or pad-to-pad bonding operations, which can be performed at a device level, at a strip-level, a panel level, or at a wafer level.

Stage 6 of FIG. 3B illustrates a state after formation of an interposer structure 338 and after various interconnect conductors 332 and conductive posts 334 are formed on or coupled to the interposer structure 338. For example, the interposer structure 338 can include or correspond to an example of the interposer structure 112 of FIG. 1 or FIG. 2. In the example illustrated in FIG. 3B, the interposer structure 338 is a pre-formed interposer structure (also referred to as interposer device) as distinct from an interposer structure that includes redistribution layers formed in place on a packaged IC device as described with reference to FIG. 4. As described with reference to FIG. 1, a pre-formed interposer structure (e.g., the interposer structure 338) is formed on a carrier 330 by stacking various patterned metal layers and dielectric layers to define conductive structures 340 and supporting dielectric materials. Although the interposer structure 338 can be formed using device-level operations, it would generally be more efficient to use strip-level, panel-level, or wafer-level operations. For example, the carrier 330 can correspond to or include a carrier wafer upon which multiple instances of the interposer structure 338 are formed concurrently.

In the example of FIG. 3B, the interconnect conductors 332 are illustrated as balls (e.g., copper-core balls); however, the interconnect conductors 332 can include conductive pillars (e.g., copper pillars) or other similar structures in other embodiments. The interconnect conductors 332 can be pre-formed (e.g., formed separately from the interposer structure 338) and coupled to the interposer structure 338 using operations such as solder reflow. Alternatively, the interconnect conductors 332 can be formed in place on the interposer structure 338 using metal deposition operations, such as plating.

Similarly, in FIG. 3B, the conductive posts 334 can be pre-formed (e.g., formed separately from the interposer structure 338) and coupled to the interposer structure 338 using operations such as solder reflow. Alternatively, the conductive posts 334 can be formed in place on the interposer structure 338 using metal deposition operations, such as plating. Irrespective of whether the conductive posts 334 are pre-formed or formed in place, solder caps 336 can be formed on the conductive posts 334 before Stage 6 of FIG. 3B.

Stage 7 of FIG. 3B illustrates a state after separation of the interposer structure 338 from the carrier 330 and during attachment of the interposer structure 338 to the die 302 and the substrate 320 from Stage 5 of FIG. 3A. For example, the interposer structure 338 of Stage 6 can be detached from the carrier 330, flipped, aligned with respect to the die 302 and the substrate 320, and attached to the die 302 and the substrate 320 by reflow of solder of the interconnect conductors 332 and the solder caps 336 of the conductive posts 334. Although the interposer structure 338 can be attached to the die 302 and the substrate 320 using device-level operations, it may generally be more efficient to use strip-level operations, panel-level operations, or wafer-level operations.

Stage 8 of FIG. 3B illustrates a state after mold compound 354 is disposed between the interposer structure 338 and the substrate 320. For example, the mold compound 354 can include or correspond to an example of the mold compound 118 of FIG. 1 or FIG. 2. The mold compound 354 at least partially encapsulates the die 302, the conductive posts 334, the interconnect conductors 332, or a combination thereof. For example, in FIG. 3B, the mold compound 354 substantially fills a region between the interposer structure 338 and the substrate 320. The mold compound 354 can be injected into the region between the interposer structure 338 and the substrate 320 as a liquid or gel and subsequently cured. The mold compound 354 can be formed in the region between the interposer structure 338 and the substrate 320 using device-level, strip-level, panel-level, or wafer-level operations.

In some embodiments, formation of a device 300 is complete at Stage 8 of FIG. 3B. For example, the device 300 can be used as a component (e.g., a packaged IC device) of a larger electronic assembly, either by the entity that fabricated the device 300 or by another entity (e.g., a customer of the entity that fabricated the device 300). To illustrate, the device 300 can correspond to or include an example of the device 100 of FIG. 1 or the device 200 of FIG. 2. In this example, the device 300 can be coupled to one or more components and/or packaged IC devices (such as the device 150) to form a POP device, such as the POP device 190 of FIG. 1 or the POP device 290 of FIG. 2. Optionally, interconnect conductors 356 can be attached to the device 300 at the state illustrated at Stage 8.

Although certain Stages of fabrication of the device 300 are illustrated in FIGS. 3A and 3B, other processes can be included in the fabrication of the device 300 without departing from the scope of the subject disclosure. For example, as noted at various Stages of FIGS. 3A and 3B, many or all of the operations described with reference to FIGS. 3A and 3B can be performed at the device level, in which case a single device 300 is formed. However, many or all of the operations described with reference to FIGS. 3A and 3B can alternatively be performed at the strip level, the panel level, or the wafer level, in which case multiple instances of the device 300 can be formed concurrently. When multiple instances of the device 300 are formed concurrently, the operations can include singulation of the devices, in which case the device 300 at Stage 8 represents a single instance of the device 300 that has been separated from other devices formed at the same time using singulation operations such as sawing, laser cutting, etc.

FIG. 4 illustrates an alternative sequence that may be used in place of a portion of the sequence of FIGS. 3A and 3B. Specifically, the operations described with reference to FIG. 4 can be used rather than the operations described with reference to Stages 6-8 of FIG. 3B. For example, Stage 1 of FIG. 4 begins after the die 302 is attached to the substrate 320 as described with reference to Stage 5 of FIG. 3A.

Stage 1 of FIG. 4 illustrates a state after the interconnect conductors 332 are attached to the substrate 320. In the example of FIG. 4, the interconnect conductors 332 are illustrated as balls (e.g., copper-core balls); however, the interconnect conductors 332 can include conductive pillars (e.g., copper pillars) or other similar structures in other embodiments. Further, in the example of FIG. 4, the interconnect conductors 332 are pre-formed (e.g., formed separately from the substrate 320) and coupled to the substrate 320 using operations such as solder reflow. In other examples, the operations associated with Stage 1 of FIG. 4 can be omitted and the interconnect conductors 332 can be formed in place on the substrate 320 using metal deposition operations, such as plating, as described with reference to Stage 2 of FIG. 4. The interconnect conductors 332 can be attached to or formed on the substrate 320 using device-level operations, strip-level operations, panel-level operations, or wafer-level operations.

Stage 2 of FIG. 4 illustrates a state after formation of the mold compound 354 and formation of openings 402 within the mold compound 354. In the example illustrated in FIG. 4, the openings 402 are aligned with the thermally conductive structures 312 of the die 302. In other examples, such as during fabrication of the device 200 of FIG. 2, the openings 402 are aligned with contacts on the back (e.g., the second side 306) of the die 302. The mold compound 354 can be formed and patterned to define the openings 402 using device-level operations, strip-level operations, panel-level operations, or wafer-level operations.

The mold compound 354 can include or correspond to an example of the mold compound 118 of FIG. 1 or FIG. 2. At Stage 2 of FIG. 4, the mold compound 354 at least partially encapsulates the die 302. The mold compound 354 can be deposited onto the die 302 and the substrate 320 as a liquid or gel and subsequently cured.

The openings 402 can be formed using various material removal operations, such as laser drilling, etching, mechanical drilling, etc. As noted above, in some embodiments, the interconnect conductors 332 are not attached to the substrate 320 at Stage 2. Rather, in such embodiments, the mold compound 354 includes additional openings (not shown) sized to accommodate the interconnect conductors 332 and exposing contacts of the substrate 320.

Stage 3 of FIG. 4 illustrates a state after the thermally conductive posts 334 are formed in thermal contact with the thermally conductive structures 312 or contacts on the second side 306 of the die 302. For example, the thermally conductive posts 334 can be formed in place within the openings 402 using one or more deposition techniques, such as CVD, PVD, sputtering, plating, or a combination thereof. When the thermally conductive posts 334 can be formed in place, the solder caps 336 of FIG. 3B can be omitted, and the thermally conductive posts 334 can be deposited directly on the thermally conductive structures 312 or contacts on the second side 306 of the die 302. Alternatively, a seed layer can be disposed between the thermally conductive posts 334 and the thermally conductive structures 312 or contacts on the second side 306 of the die 302. Formation of the thermally conductive posts 334 can be performed using device-level operations, strip-level operations, panel-level operations, or wafer-level operations.

Stage 4 of FIG. 4 illustrates a state after formation of the interposer structure 338 on the mold compound 354, the interconnect conductors 332, and the thermally conductive posts 334. For example, the interposer structure 338 can include or correspond to an example of the interposer structure 112 of FIG. 1 or FIG. 2. In the example illustrated in FIG. 4, the interposer structure 338 includes redistribution layers formed in place on the mold compound 354, the interconnect conductors 332, and the thermally conductive posts 334. To illustrate, the mold compound 354, the interconnect conductors 332, and the thermally conductive posts 334 can be planarized and/or pre-treated (if needed) to prepare a surface on which the interposer structure 338 will be formed. Various patterned metal layers and dielectric layers are subsequently formed on or attached to the surface to form the conductive structures 340 and supporting dielectric materials of the interposer structure 338. The interposer structure 338 can be formed using device-level operations, strip-level operations, panel-level operations, or wafer-level operations.

In some embodiments, formation of a device 400 is complete at Stage 4 of FIG. 4. For example, the device 400 can be used as a component (e.g., a packaged IC device) of a larger electronic assembly, either by the entity that fabricated the device 400 or by another entity (e.g., a customer of the entity that fabricated the device 400). To illustrate, the device 400 can correspond to or include an example of the device 100 of FIG. 1 or the device 200 of FIG. 2. In this example, the device 400 can be coupled to one or more components and/or packaged IC devices (such as the device 150) to form a POP device, such as the POP device 190 of FIG. 1 or the POP device 290 of FIG. 2. Optionally, the interconnect conductors 356 can be attached to the device 400 at the state illustrated at Stage 4.

Although certain Stages during fabrication of the device 400 are illustrated in FIG. 4, other processes can be included in the fabrication of the device 400 without departing from the scope of the subject disclosure. For example, as noted at various Stages of FIG. 4, many or all of the operations described with reference to FIG. 4 can be performed at the device level, in which case a single device 400 is formed. However, many or all of the operations described with reference to FIG. 4 can alternatively be performed at the strip level, the panel level, or the wafer level, in which case multiple instances of the device 400 can be formed concurrently. When multiple instances of the device 400 are formed concurrently, the operations can include singulation of the devices, in which case the device 400 at Stage 4 represents a single instance of the device 400 that has been separated from other devices formed at the same time using singulation operations such as sawing, laser cutting, etc.

### Exemplary Flow Diagram of a Method for Fabricating a Device Including Conductive Posts Thermally Coupling a Die and an Interposer Structure

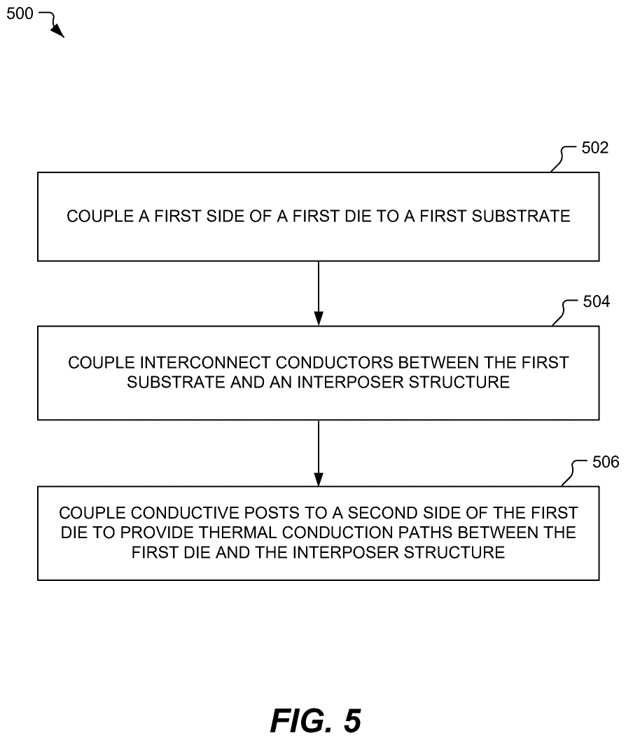

In some implementations, fabricating a device that includes conductive posts thermally coupling a die and an interposer structure includes several processes. FIG. 5 illustrates an exemplary flow diagram of a method 500 of fabricating an illustrative device that includes conductive posts thermally coupling a die and an interposer structure. In a particular aspect, one or more operations of the method 500 are initiated, performed, or controlled by one or more processors of a fabrication system. In some implementations, operations of the method 500 may be stored as instructions by a non-transitory computer-readable storage medium, and the instructions may be executable by at least one processor to cause the at least one processor to perform operations of the method 500. In some implementations, the method 500 of FIG. 5 may be used to provide or fabricate any of the device 100 of FIG. 1, the POP device 190 of FIG. 1, the device 200 of FIG. 2, the POP device 290 of FIG. 2, the device 300 of FIG. 3B, or the device 400 of FIG. 4.

It should be noted that the method 500 of FIG. 5 may combine one or more processes in order to simplify and/or clarify the method for providing or fabricating a device (e.g., a packaged IC device or a POP device). In some implementations, the order of the processes may be changed or modified.

The method 500 includes, at block 502, coupling a first side of a first die to a first substrate. For example, Stage 5 of FIG. 3A illustrates and describes examples of coupling the first side 308 of the die 302 to the substrate 320. The first die can correspond to or include the die 104 of FIG. 1 or the die 204 of FIG. 2. For example, the first die can include the embedded thermally conductive structures 124 as described with reference to FIG. 1. Alternatively, the die can include the contacts 224 as described with reference to FIG. 2. The first side of the first die can correspond to a face of the first die (e.g., a side of the first die that bounds or is proximate to an active region of the first die). The first die can be coupled to the first substrate using die attach operations, such as solder reflow or pad-to-pad bonding.

The method 500 includes, at block 504, coupling interconnect conductors between the first substrate and an interposer structure. For example, the interconnect conductors can correspond to or include the interconnect conductors 108 of FIG. 1, the interconnect conductors 332 of FIG. 3B, or the interconnect conductors 332 of FIG. 4. As described with reference to Stages 1-3 of FIG. 4, the interconnect conductors 332 can be pre-formed and subsequently attached to the substrate 320 using solder, or the interconnect conductors 332 can be formed in place on the substrate 320 using deposition operations. In some examples, such as the example described with reference to Stages 6 and 7 of FIG. 3B, the interconnect conductors 332 can be formed in place or attached to an interposer structure 338, and subsequently attached to the substrate 320.

The method 500 includes, at block 506, coupling conductive posts to a second side of the first die to provide thermal conduction paths between the first die and the interposer structure. For example, the conductive posts can correspond to or include the conductive posts 122 of FIG. 1 or FIG. 2 or the conductive posts 334 of FIG. 3B or FIG. 4. As described with reference to Stages 2 and 3 of FIG. 4, the conductive posts 334 can be formed in place on the first die (e.g., the die 302) using deposition operations. Alternatively, as described with reference to Stages 6 and 7 of FIG. 3B, the conductive posts 334 can be formed in place on or attached to an interposer structure 338, and subsequently attached to the die 302.

In some implementations, the method 500 also includes disposing mold compound between the first substrate and the interposer structure such that the mold compound at least partially encapsulates the first die, the interconnect conductors, and the conductive posts. For example, as described with reference to Stage 8 of FIG. 3B, the mold compound 354 can be injected as a liquid or gel into a region between the substrate 320 and the interposer structure 338 and subsequently cured to at least partially encapsulate the die 302, the interconnect conductors 32, and the conductive posts 334. As another example, as described with reference to Stages 2-4 of FIG. 4, the mold compound 354 can be deposited on the substrate 320, the die 302, and optionally the interconnect conductors 332 and be cured. In this example, openings can be formed in the mold compound 354 for the conductive posts 334, and optionally for the interconnect conductors 332, such that the mold compound 354 at least partially encapsulates the die 302, the interconnect conductors 332, and the conductive posts 334.

In some implementations, the method 500 also includes coupling a second die to a second substrate (e.g., to form a second packaged IC device) and coupling the second substrate to the interposer structure (e.g., to form a POP device). For example, the second die can include or correspond to the die 132 of FIG. 1 or FIG. 2, which is attached to the substrate 134 (e.g., a second substrate) to form the device 150. Further, in this example, the device 150 is coupled, via conductive interconnects 152, to the interposer structure 112 to form the POP device 190 of FIG. 1 or the POP device 290 of FIG. 2.

### Exemplary Electronic Devices

FIG. 6 illustrates various electronic devices that may include or be integrated with any of the device 100, the POP device 190, the device 200, the POP device 290, the device 300, the device 400, or another device that includes conductive posts thermally coupling a die and an interposer structure as disclosed herein. For example, a mobile phone device 602, a laptop computer device 604, a fixed location terminal device 606, a wearable device 608, or a vehicle 610 (e.g., an automobile or an aerial device) may include a device 600. The device 600 can include, for example, the device 100, the POP device 190, the device 200, the POP device 290, the device 300, the device 400, or another device that includes conductive posts thermally coupling a die and an interposer structure as disclosed herein. The devices 602, 604, 606 and 608 and the vehicle 610 illustrated in FIG. 6 are merely exemplary. Other electronic devices may also feature the device 600 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in vehicles (e.g., autonomous vehicles), or any other device that stores or retrieves data or computer instructions, or any combination thereof.

One or more of the components, processes, features, and/or functions illustrated in FIG. 1-6 may be rearranged and/or combined into a single component, process, feature or function or embodied in several components, processes, or functions. Additional elements, components, processes, and/or functions may also be added without departing from the disclosure. It should also be noted FIG. 1-6 and its corresponding description in the present disclosure is not limited to dies and/or ICs. In some implementations, FIG. 1-6 and its corresponding description may be used to manufacture, create, provide, and/or produce devices and/or integrated devices. In some implementations, a device may include a die, an integrated device, an embedded multi-chip package, an integrated passive device (IPD), a die package, an IC device, a device package, an IC package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first,” “second,” “third,” and “fourth” (and/or anything above fourth) is arbitrary. Any of the components described may be the first component, the second component, the third component or the fourth component. For example, a component that is referred to as a second component, may be the first component, the second component, the third component or the fourth component. The terms “encapsulate,” “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

According to Example 1, a device includes a substrate and a die including a first side electrically coupled to the substrate. The device includes interconnect conductors electrically coupled to the die through conductive paths of the substrate. The device also includes an interposer structure. The interposer structure includes a first side including first contacts electrically coupled to the interconnect conductors; a second side including second contacts; and a plurality of patterned conductive structures electrically coupled to the first contacts and to the second contacts. The device further includes a plurality of conductive posts between a second side of the die and the first side of the interposer structure and configured to conduct heat from the die to the interposer structure.

Example 2 includes the device of Example 1 and further includes mold compound disposed between the substrate and the interposer structure, wherein the mold compound at least partially encapsulates the die.

Example 3 includes the device Example 2, wherein the mold compound encapsulates one or more of the plurality of conductive posts.

Example 4 includes the device of Example 2 or Example 3, wherein the interposer structure corresponds to or includes redistribution layers formed on the mold compound.

Example 5 includes the device of any of Examples 1 to 4, wherein the die includes embedded thermally conductive structures, and wherein a conductive post of the plurality of conductive posts is coupled by solder to an embedded thermally conductive structure of the embedded thermally conductive structures.

Example 6 includes the device of Example 5, wherein the embedded thermally conductive structures include metal filled vias in the die.

Example 7 includes the device of any of Examples 1 to 6, wherein the first side of the die corresponds to a face of the die that bounds an active region of the die, and wherein the second side of the die corresponds to a back of the die opposite the face.

Example 8 includes the device of any of Examples 1 to 3 or Examples 5 to 7, wherein the interposer structure includes an interposer device including a plurality of patterned metal layers and laminate dielectric layers.

Example 9 includes the device of any of Examples 1 to 8, wherein the interconnect conductors include copper-core solder balls.

According to Example 10, an integrated device includes a first substrate and a first die. The first die includes a first side and a second side, wherein the first side of the first die is electrically coupled to the first substrate. The integrated device includes a second die and an interposer structure disposed between the first die and the second die. The interposer structure includes conductive paths that electrically couple the first die and second die. The integrated device includes a plurality of conductive posts between the second side of the first die and a first side of the interposer structure and configured to conduct heat from the die to the interposer structure.

Example 11 includes the integrated device of Example 10 and further includes mold compound disposed between the first substrate and the interposer structure, wherein the mold compound at least partially encapsulates the first die.

Example 12 includes the integrated device of Example 11, wherein the mold compound encapsulates one or more of the plurality of conductive posts.

Example 13 includes the integrated device of Example 11 or Example 12, wherein the interposer structure corresponds to or includes redistribution layers formed on the mold compound.

Example 14 includes the integrated device of any of Examples 10 to 13 and further includes interconnect conductors disposed between the interposer structure and the first substrate and electrically coupled to the first die through conductive paths of the first substrate.

Example 15 includes the integrated device of Example 14, wherein the interconnect conductors include copper-core solder balls.

Example 16 includes the integrated device of any of Examples 10 to 15, wherein the interposer structure includes the first side and a second side, wherein the first side of the interposer structure includes first contacts electrically coupled to interconnect conductors, and the second side includes second contacts electrically coupled to the second die. The interposer structure also includes a plurality of patterned conductive structures electrically coupled to the first contacts and to the second contacts.

Example 17 includes the integrated device of any of Examples 10 to 16, wherein the first die includes embedded thermally conductive structures, and wherein a conductive post of the plurality of conductive posts is coupled by solder to an embedded thermally conductive structure of the embedded thermally conductive structures.

Example 18 includes the integrated device of Example 17, wherein the embedded thermally conductive structures include metal filled vias in the first die.

Example 19 includes the integrated device of any of Examples 10 to 18, wherein the first side of the first die corresponds to a face of the first die that bounds an active region of the first die, and wherein the second side of the first die corresponds to a back of the first die opposite the face.

Example 20 includes the integrated device of any of Examples 10 to 12 or Examples 14 to 19, wherein the interposer structure includes an interposer device including a plurality of patterned metal layers and laminate dielectric layers.

Example 21 includes the integrated device of any of Examples 10 to 20 and further includes a second substrate that includes a first side including first contacts electrically coupled to the interposer structure; a second side including second contacts electrically coupled to the second die; and a plurality of patterned conductive structures electrically coupled to the first contacts and to the second contacts.

Example 22 includes the integrated device of any of Examples 10 to 21, wherein the first die includes circuitry that defines one or more processor cores and the second die includes circuitry that defines a plurality of memory cells.

According to Example 23, a method includes coupling a first side of a first die to a first substrate; coupling interconnect conductors between the first substrate and an interposer structure; and coupling conductive posts to a second side of the first die to provide thermal conduction paths between the first die and the interposer structure.

Example 24 includes the method of Example 23 and further includes disposing mold compound between the first substrate and the interposer structure such that the mold compound at least partially encapsulates the first die, the interconnect conductors, and the conductive posts.

Example 25 includes the method of Example 23 or Example 24 and further includes coupling a second die to a second substrate; and coupling the second substrate to the interposer structure.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A device comprising:
a substrate;
a die including a first side electrically coupled to the substrate;
interconnect conductors electrically coupled to the die through conductive paths of the substrate;
an interposer structure including:
a first side including first contacts electrically coupled to the interconnect conductors;
a second side including second contacts; and
a plurality of patterned conductive structures electrically coupled to the first contacts and to the second contacts; and
a plurality of conductive posts between a second side of the die and the first side of the interposer structure and configured to conduct heat from the die to the interposer structure.

2. The device of claim 1, further comprising mold compound disposed between the substrate and the interposer structure, wherein the mold compound at least partially encapsulates the die and one or more of the plurality of conductive posts.

3. The device of claim 2, wherein the interposer structure corresponds to or includes redistribution layers formed on the mold compound.

4. The device of claim 1, wherein the die includes embedded thermally conductive structures, and wherein a conductive post of the plurality of conductive posts is coupled by solder to an embedded thermally conductive structure of the embedded thermally conductive structures.

5. The device of claim 1, wherein the first side of the die corresponds to a face of the die that bounds an active region of the die, and wherein the second side of the die corresponds to a back of the die opposite the face.

6. The device of claim 1, wherein the interposer structure includes an interposer device including a plurality of patterned metal layers and laminate dielectric layers.

7. An integrated device comprising:
a first substrate;
a first die including a first side and a second side, wherein the first side of the first die is electrically coupled to the first substrate;
a second die;
an interposer structure disposed between the first die and the second die and including conductive paths that electrically couple the first die and second die; and
a plurality of conductive posts between the second side of the first die and a first side of the interposer structure and configured to conduct heat from the first die to the interposer structure.

8. The integrated device of claim 7, further comprising mold compound disposed between the first substrate and the interposer structure, wherein the mold compound at least partially encapsulates the first die and one or more of the plurality of conductive posts.

9. The integrated device of claim 8, wherein the interposer structure corresponds to or includes redistribution layers formed on the mold compound.

10. The integrated device of claim 7, further comprising interconnect conductors disposed between the interposer structure and the first substrate and electrically coupled to the first die through conductive paths of the first substrate.

11. The integrated device of claim 7, wherein the interposer structure includes:
the first side including first contacts electrically coupled to interconnect conductors;
a second side including second contacts electrically coupled to the second die; and
a plurality of patterned conductive structures electrically coupled to the first contacts and to the second contacts.

12. The integrated device of claim 7, wherein the first die includes embedded thermally conductive structures, and wherein a conductive post of the plurality of conductive posts is coupled by solder to an embedded thermally conductive structure of the embedded thermally conductive structures.

13. The integrated device of claim 12, wherein the embedded thermally conductive structures include metal filled vias in the first die.

14. The integrated device of claim 7, wherein the first side of the first die corresponds to a face of the first die that bounds an active region of the first die, and wherein the second side of the first die corresponds to a back of the first die opposite the face.

15. The integrated device of claim 7, wherein the interposer structure includes an interposer device including a plurality of patterned metal layers and laminate dielectric layers.

16. The integrated device of claim 7, further comprising a second substrate comprising:
a first side including first contacts electrically coupled to the interposer structure;
a second side including second contacts electrically coupled to the second die; and
a plurality of patterned conductive structures electrically coupled to the first contacts and to the second contacts.

17. The integrated device of claim 7, wherein the first die includes circuitry that defines one or more processor cores and the second die includes circuitry that defines a plurality of memory cells.

18. A method comprising:
coupling a first side of a first die to a first substrate;
coupling interconnect conductors between the first substrate and an interposer structure; and
coupling conductive posts to a second side of the first die to provide thermal conduction paths between the first die and the interposer structure.

19. The method of claim 18, further comprising disposing mold compound between the first substrate and the interposer structure such that the mold compound at least partially encapsulates the first die, the interconnect conductors, and the conductive posts.

20. The method of claim 18, further comprising:
coupling a second die to a second substrate; and
coupling the second substrate to the interposer structure.
